(19) United States
(12) Patent Application Publication
(10) Pub. No.: US 2026/0060037 A1
(43) Pub. Date: Feb. 26, 2026

(54) SUBSTRATE PROCESSING APPARATUS

(71) Applicant: Samsung Electronics Co., Ltd., Suwon-si (KR)

(72) Inventors: Hangyul LEE, Suwon-si (KR); Woojin NAM, Suwon-si (KR); Soon Ku KWON, Suwon-si (KR); Inhye JEONG, Suwon-si (KR); Sunggil KANG, Suwon-si (KR); Sung Yong PARK, Suwon-si (KR); Chanyeong JEONG, Suwon-si (KR)

(73) Assignee: Samsung Electronics Co., Ltd., Suwon-si (KR)

(21) Appl. No.: 19/056,930

(22) Filed: Feb. 19, 2025

(30) Foreign Application Priority Data
Aug. 22, 2024 (KR) 10-2024-0113112

(51) Int. Cl. H01L 21/687; G02F 1/1333; G02F 1/155

(52) U.S. Cl. CPC H01L 21/68785; G02F 1/133385; G02F 1/155

(57) ABSTRACT

Provided is a substrate processing apparatus including a chamber defining a substrate processing space, a supporting plate inside the chamber and comprising an upper surface configured to seat a substrate, a temperature controlling plate facing at least a portion of the supporting plate, and at least one electrochromic module at the temperature controlling plate, and configured to change light transmittance depending on applied electrical energy.

### CROSS-REFERENCE TO RELATED APPLICATIONS

This application claims the benefit of Korean Patent Application No. 10-2024-0113112, filed on Aug. 22, 2024, in the Korean Intellectual Property Office, the disclosure of which is incorporated herein by reference in its entirety.

### BACKGROUND

Some example embodiments relate to a substrate processing apparatus.

In general, to manufacture a semiconductor device, a series of processes such as one or more of deposition, etching, and cleaning may be performed. The processes can be accomplished through an apparatus or tool for deposition, etching and cleaning including a substrate supporting unit that is placed in a chamber and/or a process chamber and configured to heat and/or cool a substrate.

In such processing apparatuses, uneven temperature distribution of the substrate supporting unit caused by the asymmetric structure of the chamber can result in uneven substrate processing. Therefore, a substrate processing apparatus by which the temperature uniformity of a substrate supporting unit is improved is being pursued.

### SUMMARY

Some example embodiments may provide a substrate processing apparatus by which the temperature uniformity of a substrate is improved by increasing the temperature uniformity of a substrate supporting member.

Alternatively or additionally, some example embodiments may provide a substrate processing apparatus by which temperature uniformity of a substrate supporting member is improved while maintaining the continuity of the semiconductor manufacturing process.

However, the goals to be achieved by some example embodiments of are not limited to the technical aspects described above, and other goals may be inferred from the following example embodiments.

According to some example embodiments, there is provided a substrate processing apparatus including a chamber defining a substrate processing space, a supporting plate inside the chamber and comprising an upper surface configured to seat a substrate, a temperature controlling plate facing at least a portion of the supporting plate, and at least one electrochromic module on the temperature controlling plate, and configured to change light transmittance depending on an applied electrical energy.

Alternatively or additionally according to some example embodiments, there is provided a substrate processing apparatus including a chamber defining a substrate processing space, a supporting plate inside the chamber, and configured to heat a substrate seated on an upper surface of the supporting plate, a temperature controlling plate facing at least a portion of the supporting plate, a penetration part penetrating the temperature controlling plate, and an electrochromic module at the penetration part, and configured to change light transmittance as electrical energy is applied.

Alternatively or additionally according to some example embodiments, there is provided a substrate processing apparatus including a chamber defining a substrate processing space, a supporting plate inside the chamber, and configured to heat a substrate seated on an upper surface of the supporting plate, a temperature controlling plate facing at least a portion of the supporting plate, a first electrochromic module and a second electrochromic module at different positions on the temperature controlling plate, and the first electrochromic module and the second electrochromic module respectively configured to operate such that light transmittance changes as electrical energy is applied, and a controller configured to independently control a magnitude of the electrical energy applied to the first electrochromic module and a magnitude of the electrical energy applied to the second electrochromic module.

Additional aspects of some example embodiments will be set forth in part in the description which follows and, in part, will be apparent from the description, or may be learned by practice of the disclosure.

According to example embodiments, it may be possible to provide a substrate processing apparatus by which the temperature uniformity of a substrate is improved by increasing the temperature uniformity of a substrate supporting member.

Alternatively or additionally according to some example embodiments, it may be possible to provide a substrate processing apparatus by which the temperature uniformity of a substrate supporting member is improved while maintaining the continuity of the semiconductor manufacturing process.

Effects of example embodiments are not limited to those described above, and other effects may be made apparent to those of ordinary skill in the art from the following description.

### BRIEF DESCRIPTION OF THE FIGURES

These and/or other aspects, features, and advantages of inventive concepts will become apparent and more readily appreciated from the following description of example embodiments, taken in conjunction with the accompanying drawings of which:

FIG. 1 is a cross-sectional view schematically illustrating the configuration of a substrate processing apparatus according to an example embodiment;

FIG. 2 is a bottom perspective view of a substrate supporting member and a temperature controlling member according to some example embodiments;

FIG. 3 is a perspective view of a temperature controlling member according to some example embodiments;

FIG. 4 is a reference diagram illustrating the configuration of an electrochromic module included in a temperature controlling member according to some example embodiments;

FIG. 5 is a reference diagram illustrating an electrochromic module included in a temperature controlling member according to some example embodiments;

FIG. 6 to FIG. 8 are plan views of a temperature controlling member according to various example embodiments;

FIG. 9 is a plan view illustrating a part of a temperature controlling member according to some example embodiments;

FIG. 10 is a plan view illustrating a part of a temperature controlling member according to some example embodiments;

FIG. 11 is a cross-sectional view schematically illustrating the configuration of a substrate processing apparatus according to some example embodiments;

FIG. 12 is a cross-sectional view schematically illustrating the configuration of a substrate processing apparatus according to some example embodiments;

FIG. 13 is a cross-sectional diagram schematically illustrating the configuration of a substrate processing apparatus according to some example embodiments;

FIG. 14 is an exemplary plan view of a substrate supporting member and a temperature controlling member according to some example embodiments; and

FIG. 15 is a reference diagram for explaining the structure of a temperature controlling member according to some example embodiments.

### DETAILED DESCRIPTION

Prior to the detailed description of some example embodiments, terms or words used in the specification and claims should not be construed as limited to their common or dictionary meanings. Further, the terms or words should be interpreted with meaning and concept consistent with the technical idea of some example embodiments based on the principles that inventors may appropriately define the concept of terms in order to explain their inventions in the best way. Example embodiments described in this specification and the configurations shown in the drawings are some example embodiments, and do not necessarily represent the entire technical idea. Accordingly, there may be various equivalents and/or modifications that can replace them.

In the following description, singular expressions include plural expressions unless the context clearly dictates otherwise. It will be understood that, when an element (for example, a first element) is “(operatively or communicatively) coupled with/to” or “connected to” another element (for example, a second element), the element may be directly coupled with/to another element, and there may be an intervening element (for example, a third element) between the element and another element. The terms “have,” “may have,” “include,” and “may include” as used herein indicate the presence of corresponding features (for example, elements such as numerical values, functions, operations, or parts), and do not preclude the presence of additional features.

Further, in the following description, expressions such as an upper side, top, a lower side, bottom, a side, front and a back side are expressed based on the direction shown in the drawing. If the direction of the object changes, it may be expressed differently. The shapes and/or sizes of elements in the drawings may be exaggerated, for example, for clearer explanation.

Hereinafter, semiconductor packages, substrates, devices, and/or equipment and tooling according to some example embodiments will be described with reference to the attached drawings.

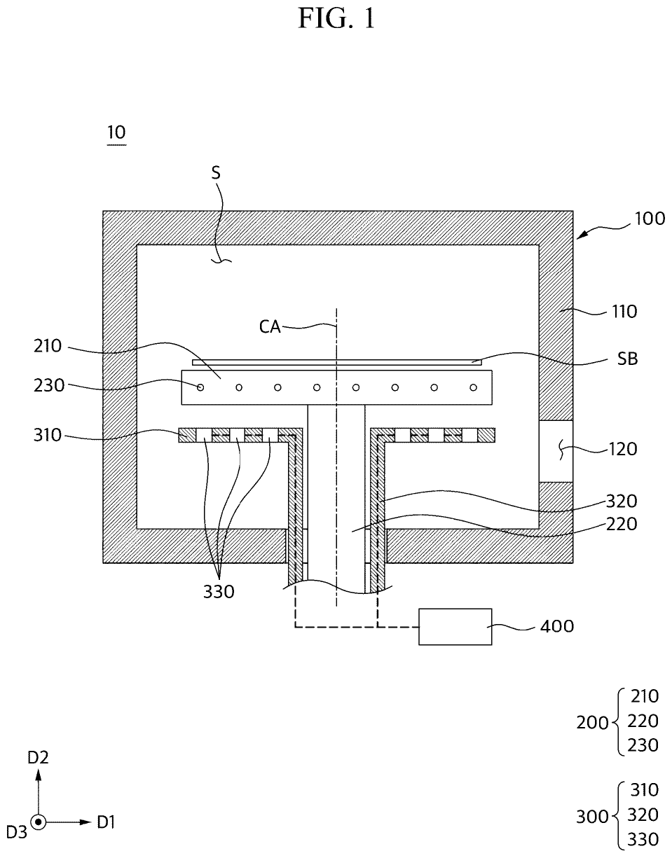

FIG. 1 is a cross-sectional view schematically illustrating the configuration of a substrate processing apparatus 10 according to some example embodiments.

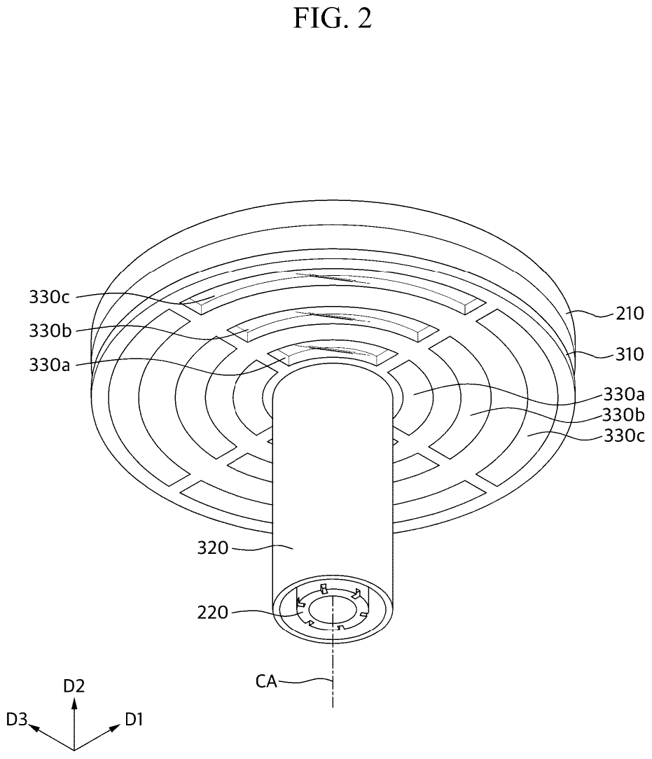

FIG. 2 is a bottom perspective view of a substrate supporting member 200 and a temperature controlling member 300 according to some example embodiments.

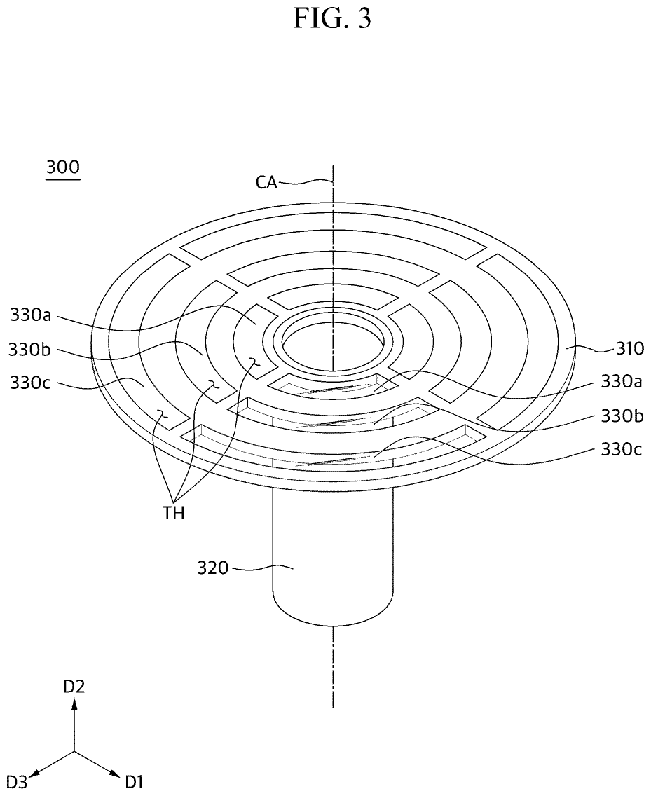

FIG. 3 is a perspective view of the temperature controlling member 300 according to some example embodiments.

According to some example embodiments, the substrate processing apparatus 10 is configured to perform a semiconductor manufacturing process. For example, the substrate processing apparatus 10 may perform one or more of a deposition process, an etching process, an ion doping process, or a cleaning process. In some example embodiments, the substrate processing apparatus 10 may be referred to as an equipment and/or a tool; example embodiments are not limited thereto.

According to some example embodiments, the substrate processing apparatus 10 may include a chamber 100 including or defining (or surrounding or enclosing) a substrate processing space S, the substrate supporting member 200 that is accommodated in the substrate processing space S and configured to support a substrate SB, and the temperature controlling member 300 configured to improve the temperature uniformity rate of the substrate supporting member 200.

According to some example embodiments, the chamber 100 of the substrate processing apparatus 10 may be the chamber 100 that is used for the semiconductor device manufacturing processes such as one or more of the deposition process, the etching process, the ion doping process, or the cleaning process. For example, the chamber 100 may be the chamber 100 that is for performing the plasma treatment process, the deposition process, the etching process and cleaning process for the substrate SB.

In some example embodiments, the chamber 100 of the substrate processing apparatus 10 may include a chamber frame 110 forming an outer wall of the chamber 100. An opening 120 to allow the substrate SB to be loaded or unloaded may be formed on one side of the chamber frame 110. While processing the substrate, the opening 120 may be closed with a door module, and after the process inside the chamber 100 is completed, the opening 120 may be opened to allow the processed substrate to be taken out of the chamber 100.

In some example embodiments, the substrate processing apparatus 10 may include the substrate supporting member 200 that is arranged in the substrate processing space S within the chamber 100 and iks configured to support, e.g., to seat, the substrate SB.

In some example embodiments, the substrate supporting member 200 may include a supporting plate 210 supporting the substrate SB and a support shaft 220 supporting the supporting plate 210.

In some example embodiments, the supporting plate 210 may support or seat the substrate SB in the semiconductor manufacturing process for the substrate SB. For example, referring to FIG. 1 and FIG. 2, the supporting plate 210 may have a circular plate shape, and the substrate SB may be mounted on the supporting plate 210. In some example embodiments, the substrate SB and the supporting plate 210 may be circular, with the supporting plate 210 having a diameter greater than, equal to, or less than that of the substate SB; example embodiments are not limited thereto. For example, the substrate SB may be supported by vacuum absorption and/or electrostatic adsorption or chucking on the upper surface of the supporting plate 210.

In some example embodiments, the support shaft 220 extends from the lower surface of the supporting plate 210 in a direction parallel to the height direction of the chamber 100 (for example, a direction D2 that intersects with, e.g., that is perpendicular to, direction D2 and/or direction D3), and structurally supports the supporting plate 210. For example, the support shaft 220 may have a cylindrical column structure that supports the lower surface of the supporting plate 210.

In some example embodiments, the support shaft 220 may be configured to ascend and/or descend in a direction parallel to the height direction of the chamber 100 (for example, the direction D2). The supporting plate 210 may ascend and/or descend in a direction parallel to or along the height direction of the chamber 100 (for example, the direction D2) within the substrate processing space S by the driven support shaft 220. In some example embodiments, the support shaft 220 may include and/or be driven by an actuator (not shown), such as a linear actuator (not shown).

In some example embodiments, the supporting plate 210 may perform a function of controlling the temperature of the substrate SB by heating or cooling the substrate SB.

In some example embodiments, the substrate supporting member 200 may include a temperature controller 230 configured to heat and/or cool the supporting plate 210. In the semiconductor manufacturing process, the temperature controller 230 may control or at least partially control the temperature of the substrate SB by controlling the temperature of the supporting plate 210. For example, referring to FIG. 1, the temperature controller 230 may be formed as a channel structure configured to allow a heat transfer fluid to flow, and be placed inside the supporting plate 210. The temperature controller 230 may, for example, have a concentric and/or a spiral shape centered on the central axis CA of the supporting plate 210. The heat transfer fluid flowing inside the temperature controller 230 may include, for example, water, ethylene glycol, silicone oil, liquid Teflon™, or a mixture thereof, such as an equal-parts mixture and/or a variable-parts mixture thereof. However, the heat transfer fluid is not limited thereto, and anything that may raise and/or lower the temperature of the supporting plate 210 within a temperature range suitable for the semiconductor manufacturing process may be the heat transfer fluid.

In some example embodiments, the chamber 100 in the substrate processing apparatus 10 may have an asymmetric structure. For example, the chamber frame 110 and the substrate processing space S may be formed asymmetrically, due to the opening 120 provided on one side of the chamber frame 110 and/or due to another structure placed inside the chamber 100 to perform the semiconductor manufacturing process. As such, when the chamber 100 in the substrate processing apparatus 10 is implemented with an asymmetric structure, a degree of radiant heat transfer between the supporting plate 210 and the chamber 100 may vary at each location on the supporting plate 210.

In some substrate processing apparatuses, when a chamber frame and a substrate processing space are formed asymmetrically, the radiant heat emitted from each part of the supporting plate may not be evenly distributed, and/or the temperature distribution of the supporting plate and the substrate supported on the supporting plate may be uneven due to the effect of radiant heat reflected from the asymmetrical structure.

According to some example embodiments, however, the substrate processing apparatus 10 may further include the temperature controlling member 300 by which the temperature uniformity rate of the supporting plate 210 and further the temperature uniformity of the substrate SB are improved.

In some example embodiments, the temperature controlling member 300 may include a temperature controlling plate 310 positioned to face at least a portion of the supporting plate 210, and a temperature control shaft 320 that supports the temperature controlling plate 310.

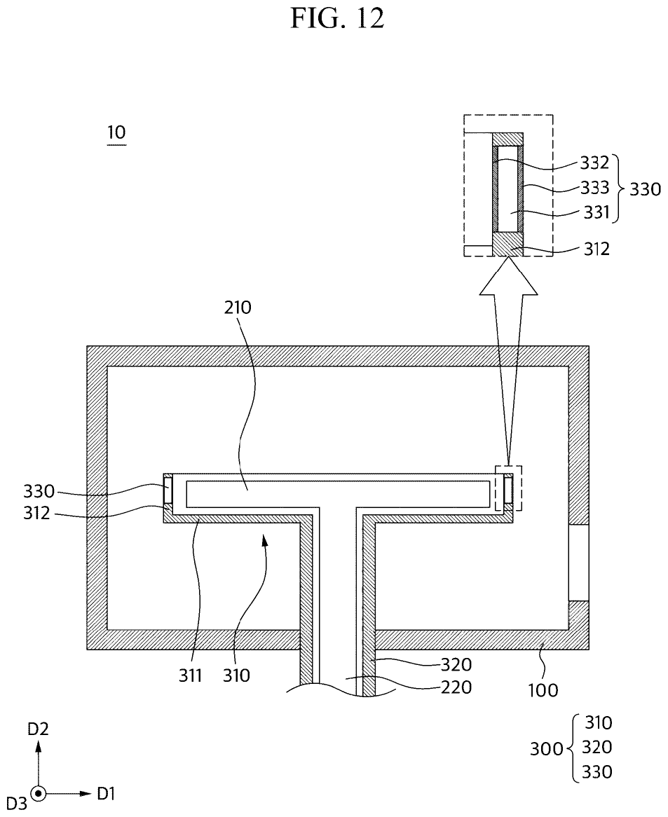

In some example embodiments, the temperature controlling plate 310 may have a circular plate shape, and may be placed facing the supporting plate 210 and the chamber 100 in the height direction. For example, referring to FIG. 1 to FIG. 3, the temperature controlling plate 310 may be placed so as to face the lower surface of the supporting plate 210, which is the opposite surface of the upper surface on which the substrate SB is mounted, in the height direction of the chamber 100 (for example, the direction D2). The temperature controlling plate 310 may be placed at a small distance from the supporting plate 210. A gap between the temperature controlling plate 310 and the supporting plate 210 may be set in various ways. The temperature controlling plate 310 may be placed in order for the central axis of the temperature controlling plate 310 to be aligned with the central axis CA of the supporting plate 210. For example, the temperature controlling plate 310 and the supporting plate 210 may have the same central axis CA. However, the arrangement structure of the temperature controlling member 300 is not limited to that described above. The temperature controlling member 300 may be placed on any position that may appropriately control the temperature uniformity rate of the supporting plate 210. For example, as described with reference to FIG. 12 to FIG. 15 later, the temperature controlling plate may be placed around one or more of the side, the corner, or the upper surface of the supporting plate 210 in order to be facing the side, the corner, or the upper surface.

Further, in some example embodiments, referring to FIG. 1 to FIG. 3, the temperature controlling plate 310 may be supported by being coupled to the temperature control shaft 320. Referring to FIG. 3, the temperature control shaft 320 may support the lower surface of the temperature controlling plate 310, and may be a cylindrical member having a hollow space formed inside. The hollow space of the temperature control shaft 320 may accommodate the support shaft 220.

In some example embodiments, the temperature control shaft 320 may be configured to be movable, e.g., independently movable, with respect to the support shaft 220. For example, the temperature control shaft 320 may be configured to ascend and descend in a direction parallel to the rising and falling direction of the support shaft 220 and/or to rotate (e.g., to be threaded) about the support shaft. For example, the ascending and descending of the temperature control shaft 320 and the ascending and descending of the support shaft 220 may be interlocked and performed together. Alternatively or additionally, the drive of the temperature control shaft 320 may be performed independently of the drive of the support shaft 220. For example, the temperature control shaft 320 may ascend or descend while the support shaft 220 is fixed, or may be rotated to tilt at an angle such as a fixed angle (or, alternatively, a predetermined angle) with respect to the support shaft 220. Accordingly, the gap between the supporting plate 210 and the temperature controlling plate 310 may be changed.

In some example embodiments, the temperature controlling plate 310 may be configured to absorb at least some of the heat and/or thermal radiation emitted from the supporting plate 210 and/or reflected to the supporting plate 210, and may pass rest of the heat. For example, the temperature controlling plate 310 may be made of or at least include materials such as at least one of quartz, aluminum, stainless steel and titanium, and the temperature controlling plate 310 may be configured to block and/or reflect some of the radiant heat radiated from the supporting plate 210. The material of the temperature controlling plate 310 is not limited to those described above. For example, anything that maintains structural stability without melting and/or collapsing under the high temperature heat energy generated from the supporting plate 210 may be formed into or included in the temperature controlling plate 310.

In some example embodiments, at least one electrochromic device and/or electrochromic module 330, of which the transmittance of radiant heat generated from the supporting plate 210 changes as power is applied, may be placed on the temperature controlling plate 310. For example, referring to FIG. 1, the temperature controlling member 300 may be coupled to the temperature controlling plate 310, and at least one electrochromic module 330 may be arranged to face the supporting plate 210 in the height direction (for example, the direction D2) of the chamber 100.

In some example embodiments, at least one electrochromic module 330 may be coupled to the temperature controlling plate 310. For example, referring to FIG. 3, the temperature controlling member may include a plurality of penetration parts TH formed by penetrating the temperature controlling plate 310 in a direction perpendicular to the lower surface of the supporting plate 210. At least one electrochromic module 330 may be placed in each of the plurality of penetration parts TH.

In some example embodiments, the electrochromic module 330 may be configured to change a light transmission rate as the electrical energy (for example, a voltage and/or a current) is applied. For example, if no electrical energy is applied to the electrochromic module 330, the electrochromic module 330 may maintain an opaque state that does not transmit light, and the electrochromic module 330 may change between a translucent state and a transparent state by the light transmission rate being increased as the electrical energy is applied. Alternatively, if the electrical energy is not applied, the electrochromic module 330 may be maintained in the transparent state, but then may be changed to the translucent state or the opaque state when the electrical energy is applied and the light transmission rate is lowered. A degree of change in the light transmission rate of the electrochromic module 330 may correspond to a magnitude of (e.g., an absolute value of) the electrical energy applied to the electrochromic module 330. For example, when the initial state of the electrochromic module 330 (for example, a state in which the electrical energy is not applied) is an opaque state, as the magnitude of the electrical energy applied to the electrochromic module 330 gradually increases, the light transmission rate of the electrochromic module 330 gradually increases. Thus, the state may be sequentially changed to the translucent state and the transparent state. As the transparency rate of the electrochromic module 330 changes, in the electrochromic module 330, not only the transmittance of visible light but also the transmittance of electromagnetic waves in the infrared and ultraviolet light ranges may be changed.

According to some example embodiments, the electrochromic module 330 of the temperature controlling member 300 may locally control the temperature of the supporting plate 210 by changing the transparency rate, and the transmittance of electromagnetic waves including infrared, visible, and ultraviolet light may be changed. For example, the temperature controlling member 300 may increase the transparency rate of some of the plurality of electrochromic modules 330 to increase the transmittance of light including infrared, visible light and ultraviolet light, causing a smooth radiation heat dissipation. Accordingly, the temperature may be lowered by more smoothly dissipating radiant heat in the vicinity of the lower portion surface of the supporting plate 210 facing the electrochromic module 330 in the transparent state. For example, while another part of the temperature controlling plate 310 is in a state where the transmission and/or emission of radiant heat is not smooth due to the temperature controlling plate 310 or the electrochromic module 330 in an opaque state, in the electrochromic module 330, which has been changed to a transparent state, the transmission or emission of radiant heat is smoother. Thus, the transmittance or emission rate of radiant heat may be locally different on the lower portion surface of the supporting plate 210.

As such, the temperature controlling member 300 according to some example embodiments may improve the temperature uniformity of the supporting plate 210 by partially changing the radiant heat transmittance of the temperature controlling plate 310 through the electrochromic module 330 configured to change the light transmission rate. For example, as illustrated in FIG. 1, when the opening 120 is formed on one side of the substrate, uneven radiation heat trapping or radiation heat reflection environments may be formed at a side where the opening 120 is placed Inside the chamber 100 and a side opposite thereto. For example, in an area adjacent to the part where the opening 120 is formed inside the chamber 100, the radiation heat dissipation may be smoother compared to other areas. In this case, the temperature controlling member 300 lowers the transparency rate of the electrochromic module 330, which is located close to the opening 120 based on the central axis CA, thereby preventing or reducing radiation heat from escaping smoothly, and control the transparency rate of the electrochromic module 330 on the opposite side to allow the radiation heat to escape smoothly. Accordingly, a difference between thermal emissivity of an area distanced far from the opening 120 and thermal emissivity of an area adjacent to the opening 120 in the supporting plate 210 is reduced, and despite the non-uniform radiation heat capture or radiation heat reflection environment inside the chamber 100, the supporting plate 210 may have an even or more even temperature distribution overall.

In some example embodiments, the substrate processing apparatus 10 may further include a controller 400 for controlling a transparency rate of the electrochromic module 330 of the temperature controlling member 300. For example, the controller 400 may control the transparency rate of the electrochromic module 330 by controlling the magnitude of the electrical energy applied to the electrochromic module 330.

In some example embodiments, the temperature controlling member 300 may include a plurality of electrochromic modules 330. For example, referring to FIG. 2 and FIG. 3, the plurality of electrochromic modules 330 may include a first electrochromic module 330a, a second electrochromic module 330b and a third electrochromic module 330c arranged radially with respect to the central axis CA of the temperature controlling plate 310. As illustrated in FIG. 2 and FIG. 3, the first electrochromic module 330a, the second electrochromic module 330b and the third electrochromic module 330c may be spaced apart from each other, e.g., by the same distance. However, unlike what is illustrated, the first electrochromic module 330a, the second electrochromic module 330b and the third electrochromic module 330c may be close to each other.

In some example embodiments, there may be a plurality of first electrochromic modules 330a, a plurality of second electrochromic modules 330b and a plurality of third electrochromic modules 330c. For example, referring to FIG. 2 and FIG. 3, the plurality of first electrochromic modules 330a may be arranged along the circumferential direction based on the central axis CA of the temperature controlling plate 310, and be arranged rotationally symmetrically about the central axis CA of the temperature controlling plate 310.

In some example embodiments, the controller 400 may independently control the plurality of first electrochromic modules 330a, the plurality of second electrochromic modules 330b, and the plurality of third electrochromic modules 330c. For example, the controller 400 may control the transparency rate of the first electrochromic module 330a, the transparency rate of the second electrochromic module 330b, and the transparency rate of the third electrochromic module 330c independently, as well as the transparency rate of some electrochromic modules different from some of the plurality of first electrochromic modules 330a independently. The controller 400 may be configured to independently control the transparency rate of the electrochromic module 330 in this way in order to form various light transmission rate patterns on the temperature controlling plate 310. For example, according to some example embodiments, the temperature controlling member 300 of the substrate processing apparatus 10 may change the light transmission rate locally in the temperature controlling plate 310 corresponding to the various asymmetric environments inside the chamber 100. Accordingly, the temperature uniformity of the supporting plate 210 and the temperature uniformity of the substrate SB may be improved.

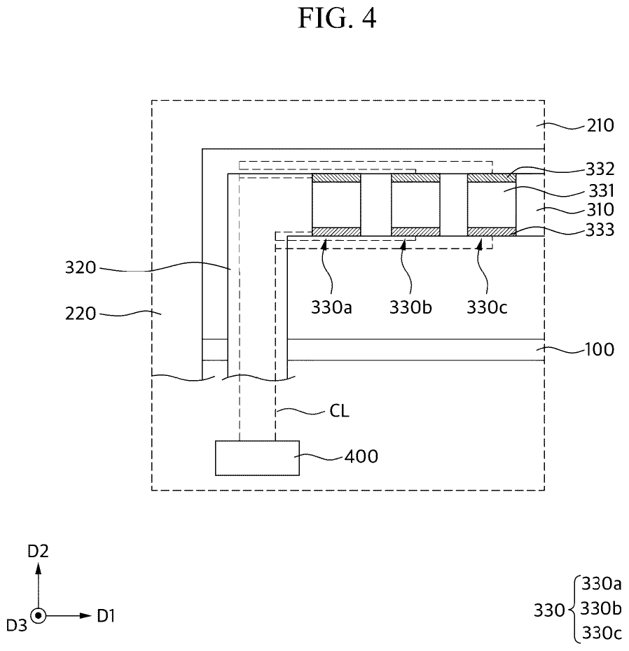

Below, various detailed example embodiments of the electrochromic module 330 of the temperature controlling member 300 are described with reference to FIG. 4 to FIG. 10.

Some example embodiments on the temperature controlling member 300 with reference to FIG. 4 to FIG. 10 include all features of the temperature controlling member 300 described with reference to FIG. 1 to FIG. 3, and thus repeated descriptions may be omitted.

FIG. 4 is a reference diagram illustrating the configuration of the electrochromic module 330 included in the temperature controlling member 300 according to some example embodiments.

In some example embodiments, the electrochromic module 330 of the temperature controlling member 300 may include a plurality of electrodes 332 and 333 arranged facing each other, and an electrochromic element arranged between the plurality of electrodes 332 and 333. The light transmission rate changes as the electrical energy is applied to the plurality of electrodes 332 and 333.

For example, referring to FIG. 4, a pair of electrodes 332 and 333 facing each other and an electrochromic element 331 positioned between the pair of electrodes 332 and 333 may be included in each of the first electrochromic module 330a, the second electrochromic module 330b, and the third electrochromic module 330c arranged along a direction parallel to the supporting plate 210 in the temperature controlling plate 310.

Further, with respect to the first electrochromic module 330a, the second electrochromic module 330b, and the third electrochromic module 330c, even though not illustrated, only one of the pair of electrodes 332 and 333 may be formed in each of the first electrochromic module 330a to the third electrochromic module 330c, and another electrode may be formed as one to be shared. Further, even though not illustrated for the electrochromic element 331, with respect to the first electrochromic module 330a, the second electrochromic module 330b and the third electrochromic module 330c, one electrochromic element may be formed to be shared.

In some example embodiments, the electrochromic element 331 may be or may include a device whose color and/or light transmission rate changes by polarization when an electrical energy is applied. For example, the electrochromic element 331 may be composed of polymer dispersed liquid crystal (PDLC), in which a transparency rate may be controlled, e.g., by an electrical energy. When the electricity is supplied to the PDLC, the liquid crystals inside align in the direction that electricity flows, allowing light to pass through and the PDLC becomes transparent. The PDLC may become opaque when no electricity is supplied, as the liquid crystals inside are arranged in a random direction, absorbing or scattering light. However, in addition to or alternatively to the PDLC described above, the electrochromic element 331 may include at least one of various elements with variable transmittance including a suspended particle display (SPD), guest-host liquid crystal (G-H LC), and electro-chromic (EC).

In some example embodiments, the plurality of electrodes 332 and 333 included in the electrochromic module 330 may be arranged facing each other with the electrochromic element 331 interposed therebetween. For example, referring to FIG. 4, the plurality of electrodes 332 and 333 may be arranged to face each other in the height direction of the chamber 100 with the electrochromic element 331 therebetween. For example, the electrode 332 arranged on one side of the electrochromic element 331 may be a positive electrode, and the electrode 333 placed on the other side of the electrochromic element 331 may be a negative electrode. As the electrical energy is applied between the positive electrode and the negative electrode, light transmission rate of the electrochromic element 331 between the positive and negative electrodes changes.

In some example embodiments, the plurality of electrodes 332 and 333 may be or may include transparent electrodes. The transparent electrode may be a transparent conducting oxide. The transparent electrode may include at least one selected from indium tin oxide (ITO), zinc-doped indium tin oxide (ZITO), zinc indium oxide (ZIO), gallium indium oxide (GIO), zinc tin oxide (ZTO), fluorine-doped tin oxide (FTO), aluminum-doped zinc oxide (AZO), gallium-doped zinc oxide (GZO), In4Sn3O12, Zn(1−x) MgxO (Zinc Magnesium Oxide, 0≤x≤1), graphene and CNT. The transparent electrode may be configured to pass the light smoothly. However, the material of the transparent electrode is not limited thereto. For example, anything that has the electrical conductivity and a sufficient light transmission rate may be used as a material of the transparent electrode.

In some example embodiments, the controller 400 may control the magnitude of (e.g., the absolute value of) the electrical energy applied to the plurality of electrodes 332 and 333 included in each electrochromic module 330. For example, the controller 400 may control different magnitudes of the electrical energy to be applied to the electrodes 332 and 333 of the first electrochromic module 330a, the electrodes 332 and 333 of the second electrochromic module 330b, and the electrodes 332 and 333 of the third electrochromic module 330c. Accordingly, the light transmission rates of the first electrochromic module 330a, the second electrochromic module 330b and the third electrochromic module 330c may be formed differently.

In some example embodiments, the controller 400 may include a power source that generates the electrical energy applied to the electrodes 332 and 333 of the electrochromic module 330, and a processor configured to control the power source.

In some example embodiments, the controller 400 may be placed outside the chamber 100, and each of the plurality of electrodes 332 and 333 in the electrochromic module 330 may be connected to the power supply of the controller 400 via a bus such as but not limited to a conductive connecting line CL. In this case, as illustrated in FIG. 4, at least a portion of the conductive connecting line CL may be arranged to extend in the longitudinal direction of the temperature control shaft 320 (for example, the direction D2) within the temperature control shaft 320. However, the arrangement of the conductive connecting line CL is not limited to what is illustrated in the drawing. For example, at least a portion of the conductive connecting line CL may extend along the length of the support shaft 220 (for example, the direction D2) inside the support shaft 220 of the substrate supporting member 200 and be connected to the controller 400 outside the chamber 100.

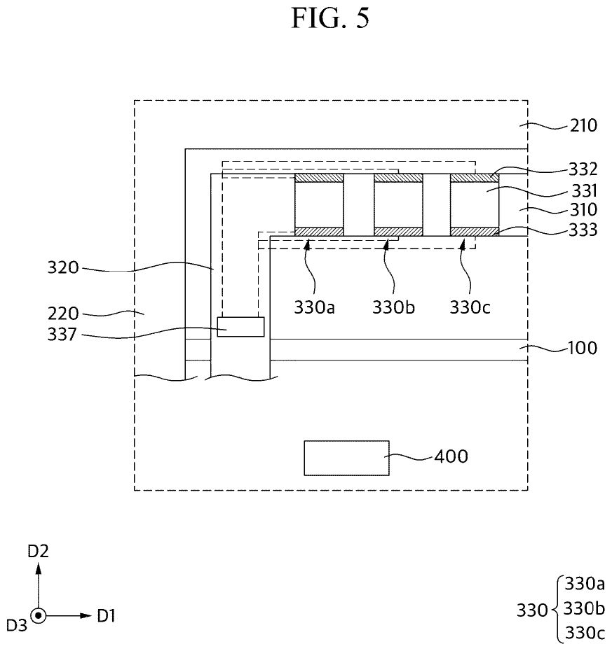

FIG. 5 is a reference diagram illustrating an electrochromic module 330 included in a temperature controlling member according to some example embodiments.

In some example embodiments, a power supply part 337 for supplying power to the electrochromic module 330 may be positioned inside the chamber 100. For example, referring to FIG. 5, the power supply part 337 is arranged inside the temperature controlling plate 310 or the temperature control shaft 320 and may include an energy storage device that stores the electrical energy.

In some example embodiments, the power supply part 337 may be placed inside the chamber 100 and may wirelessly receive a control signal from the controller 400 placed outside the chamber 100 and apply the electrical energy to the electrodes 332 and 333 of the electrochromic module 330. For this purpose, the power supply part 337 may further include a communication module configured to receive a control signal transmitted from the controller 400. For example, the communication module may be implemented as a near field communication (NFC) transceiver, but in addition thereto, various known wireless communication modules, such as but not limited to BlueTooth™ communication, may be applied.

The power line and the signal line of the electrochromic module 330 may be implemented more simply by placing the power supply part 337, which supplies power to the electrochromic module 330, inside the chamber 100 and wirelessly controlling the power supply part 337 through the controller 400.

However, the configuration of the power line and the signal line of the electrochromic module 330 of the substrate processing apparatus 10 according to some example embodiments is not limited to what is described above. For example, in some example embodiments, the electrochromic module 330 may be configured to be powered wirelessly, e.g., inductively, from the controller 400 positioned outside the chamber 100. For example, the controller 400 may also independently control the light transmission rate of each electrochromic module 330 by wirelessly supplying different magnitudes of power to each electrochromic module 330 placed at each location of the temperature controlling member 300. In this case, the wireless power supply may be implemented using wireless power transmission technologies such as magnetic induction and/or magnetic resonance. However, in addition or alternative thereto, various known wireless power supply methods may be applied.

Meanwhile, the electrochromic module 330 of the temperature controlling member 300 according to the example embodiments may have various arrangement structures.

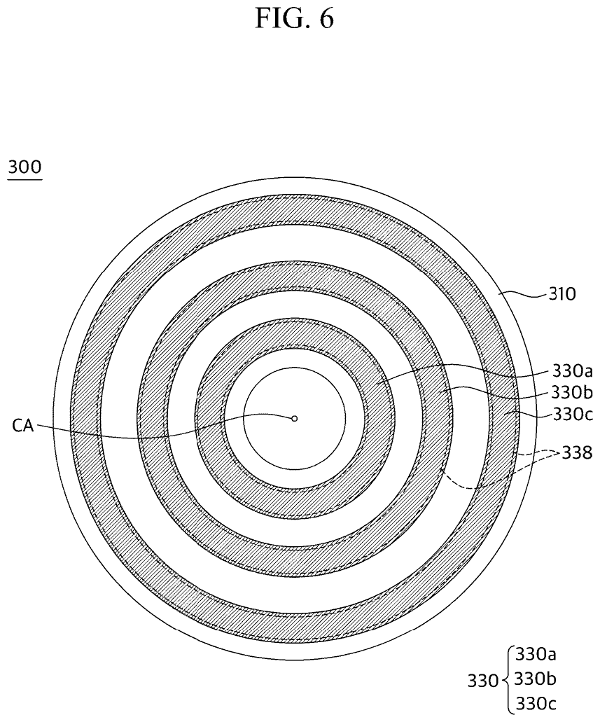

FIG. 6 to FIG. 8 are plan views of the temperature controlling member 300 according to various example embodiments.

In some example embodiments, the temperature controlling member 300 may include a plurality of electrochromic modules 330 spaced apart along the radial direction of the temperature controlling plate 310. For example, referring to FIG. 6, each electrochromic module 330 may be arranged in a concentric circle shape based on the central axis CA of the temperature controlling plate 310.

Referring to FIG. 6, each of the first electrochromic module 330a, the second electrochromic module 330b and the third electrochromic module 330c may include a single electrochromic element 331 extending in a circumferential direction relative to the central axis CA of the temperature controlling plate 310. A space between the first electrochromic module 330a and the second electrochromic module 330b may be the same as, greater than, or less than a space between the second electrochromic module 330b and the third electrochromic module 330c; example embodiments are not limited thereto. A transparent circular electrode 338 may be placed on one side and the other side of each of the electrochromic element 331.

According to the layout structure of the electrochromic module 330, with controlling the light transmission rate differently in the radial direction of the temperature controlling plate 310, the temperature uniformity rate in the radial direction of the supporting plate (for example, the supporting plate 210 in FIG. 1 and FIG. 2) may be improved. For example, in the chamber 100 environment where radiation heat release in the outer area of the supporting plate 210 occurs more smoothly than in the area adjacent to the central axis CA, the temperature controlling member 300 makes the transparency rate of the first electrochromic module 330a, which is relatively close to the central axis CA, higher than the transparency rate of the third electrochromic module 330c, which is far from the central axis CA. Thus, a gap between the radiation heat emission levels between the central and peripheral areas of the supporting plate 210 may be reduced. Accordingly, the temperature uniformity rate in the radial direction of the supporting plate 210 may be increased, and the temperature uniformity rate of the substrate SB supported on the supporting plate 210 may also be increased.

In some example embodiments, the electrochromic module 330 of the temperature controlling member 300 may include a plurality of segmented electrodes 339 arranged along a circumferential direction based on the central axis CA of the temperature controlling plate 310.

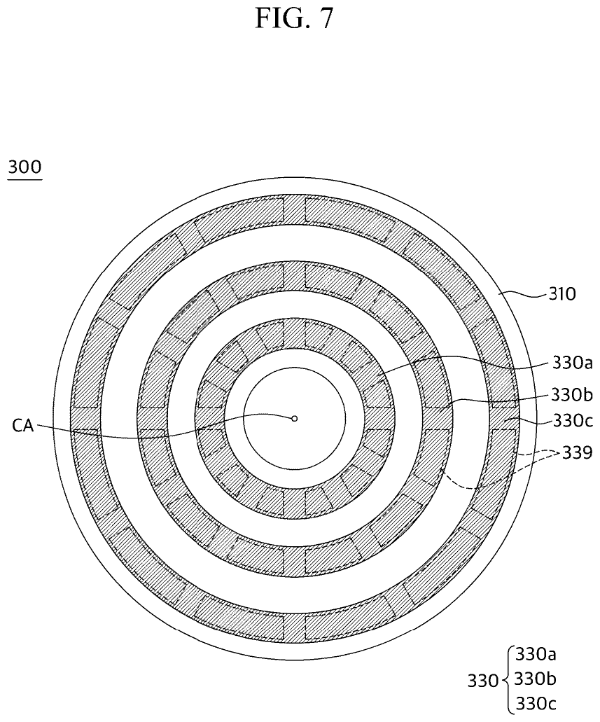

For example, referring to FIG. 7, each of the first electrochromic module 330a, the second electrochromic module 330b and the third electrochromic module 330c includes a single electrochromic element 331 extending circumferentially relative to the central axis CA of the temperature controlling plate 310, and the plurality of transparent segmented electrodes 339 may be spaced apart along the circumferential direction based on the central axis CA of the temperature controlling plate 310 on an upper surface or a lower surface of each of the plurality of electrochromic elements 331.

According to the arrangement of the electrodes 339, the light transmission rate of the temperature controlling member 300 may be controlled more precisely, e.g., more precisely with respect to a polar coordinate of the controlling plate 310. For example, when the electrical energy is applied to some of the electrodes among the plurality of segmented electrodes 339 spaced apart along the direction of the circumference based on the central axis CA of the temperature controlling plate 310, in the electrochromic element 331, the light transmission rate in the vicinity of an electrode to which the electrical energy is applied may be locally changed. Accordingly, the light transmission rate of the temperature controlling plate 310 may be finely adjusted by area.

In some example embodiments, the temperature controlling member 300 may include a plurality of electrochromic modules 330 arranged rotationally symmetrically about the central axis CA of the temperature controlling plate 310.

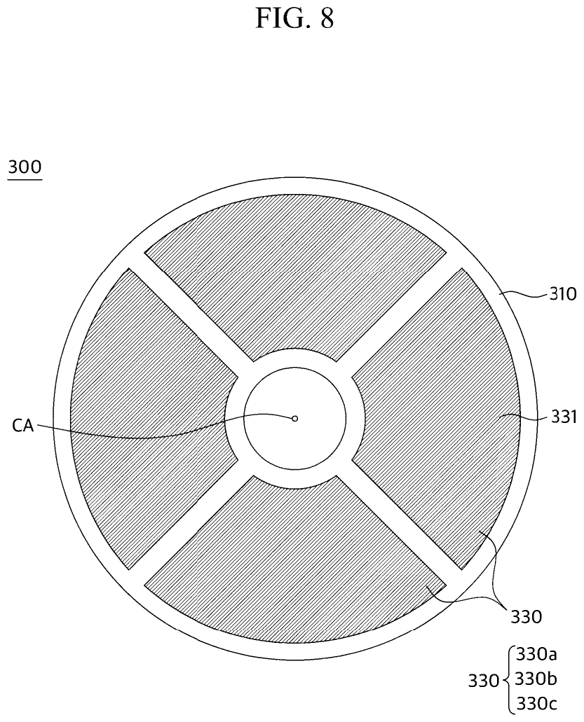

For example, referring to FIG. 8, the temperature controlling member 300 may include the plurality of large-area electrochromic modules 330 arranged along a circumferential direction based on the central axis CA of the temperature controlling plate 310. Each electrochromic module 330 may include the electrochromic element 331 whose light transmission rate changes as the electrical energy is applied. According to the layout structure of the electrochromic module 330, by controlling the light transmission rate differently in the circumferential direction of the temperature controlling plate 310, the temperature uniformity rate in the circumferential direction of the supporting plate 210 may be improved.

In some example embodiments, electrodes of various patterns may be arranged on the upper surface or lower surface of the electrochromic element 331 of the large-area electrochromic module 330. For example, the plurality of electrodes may be spaced apart from each other along the circumferential direction or the radial direction based on the central axis CA of the temperature controlling plate 310, and/or in the sloping direction in the directions on the upper surface or the lower surface of the electrochromic element 331.

Meanwhile, in some example embodiments, the electrodes of the temperature controlling member 300 may be implemented in various structures other than those described above.

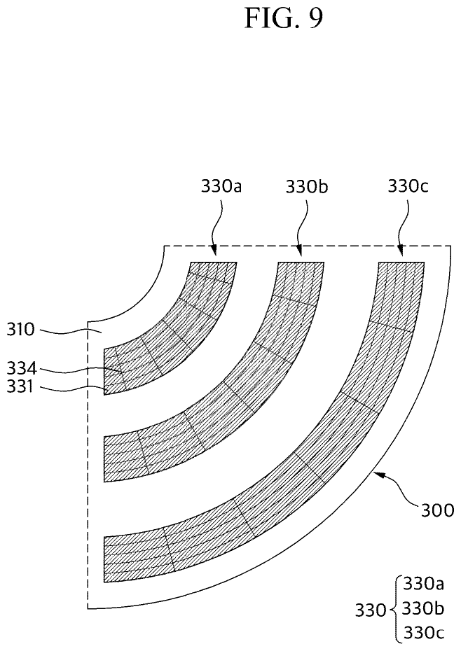

FIG. 9 is a plan view illustrating a part of the temperature controlling member 300 according to some example embodiments.

In some example embodiments, at least one of the plurality of electrodes included in the electrochromic module 330 may be configured as a lattice type (or grid pattern) electrode 334. For example, referring to FIG. 9, the temperature controlling member 300 may include the first electrochromic module 330a, the second electrochromic module 330b, and the third electrochromic module 330c, which are spaced apart from each other along the radial direction of the temperature controlling plate 310. Each electrochromic module 330 may include the electrochromic element 331 whose light transmission rate changes as the electrical energy is applied and the lattice type electrode 334 placed on the upper surface or lower surface of the electrochromic element 331.

In some example embodiments, the lattice type electrode 334 may be formed by multiple metal lines crossing each other on one side of the electrochromic element 331. For example, referring to FIG. 9, the lattice type electrode 334 may form a lattice layer extending in a direction parallel to the upper surface of the temperature controlling plate 310 from the upper surface or the lower surface of the electrochromic element 331.

When using the lattice type electrode 334, the light transmission rate of the electrode region formed on the upper surface or lower surface of the electrochromic element 331 may be sufficiently secured. Thus, the light transmission rate of the entire discoloration element may not be reduced by the electrode.

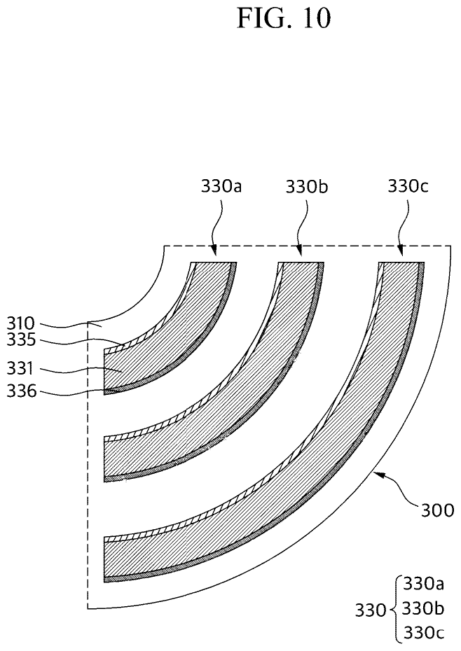

FIG. 10 is a plan view illustrating a part of the temperature controlling member 300 according to some example embodiments.

In some example embodiments, the plurality of electrodes 332 and 333 included in the electrochromic module 330 may be spaced apart from each other along the radial direction of the temperature controlling plate 310. For example, referring to FIG. 10, the temperature controlling member 300 may include the first electrochromic module 330a, the second electrochromic module 330b and the third electrochromic module 330c, which are spaced apart from each other along the radial direction of the temperature controlling plate 310. Each electrochromic module 330 may include the electrochromic element 331 whose light transmission rate changes as the electrical energy is applied and a pair of electrodes 335 and 336 spaced apart along the radial direction of the temperature controlling plate 310.

With respect to the electrochromic module 330 of some example embodiments described in FIG. 10, each of the electrodes 335 and 336 may be positioned between the electrochromic element 331 and the temperature controlling plate 310, and the upper surface and the lower surface of the electrochromic element 331 may be directly exposed on the upper surface of the temperature controlling plate 310. Accordingly, the light transmission rate of the temperature controlling member 300 may be changed more precisely and efficiently.

Alternatively or additionally, since the electrochromic module 330 may be implemented using general electrodes (for example, various opaque electrodes) as well as transparent electrodes or lattice type electrodes, the selection range of electrode materials may be increased and the cost of manufacturing the electrochromic module 330 may be reduced.

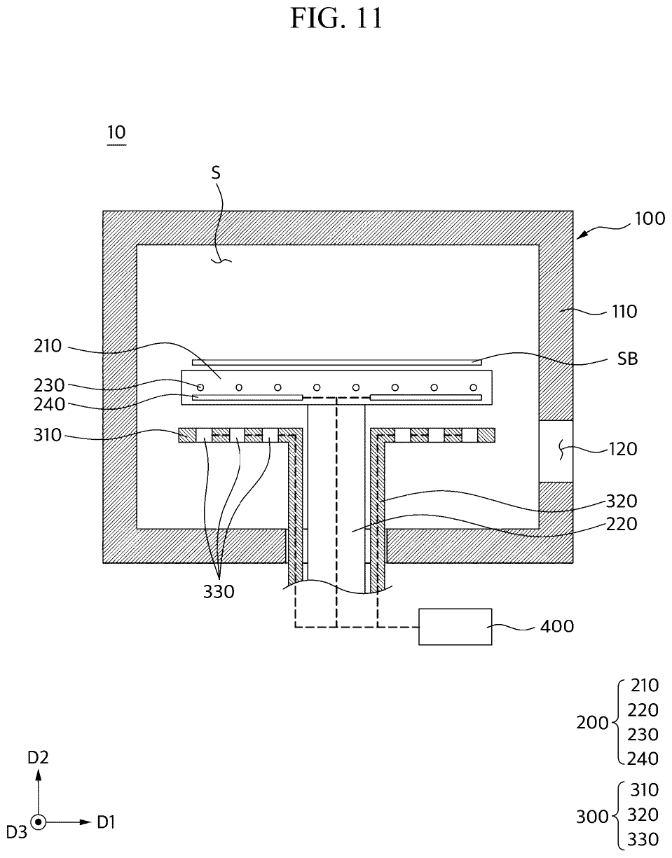

FIG. 11 is a cross-sectional view schematically illustrating the configuration of the substrate processing apparatus 10 according to some example embodiments.

In some example embodiments, the substrate processing apparatus 10 may further include a temperature sensor 240 for detecting the temperature of the substrate supporting member 200. For example, referring to FIG. 11, the substrate supporting member 200 of the substrate processing apparatus 10 may include the temperature sensor 240 disposed inside the supporting plate 210 and configure to detect the temperature of the supporting plate 210.

In some example embodiments, the temperature data of the supporting plate 210 generated from the temperature sensor 240 may be transmitted to the controller 400. The controller 400 may receive and collect measured temperature data. The controller 400 may change the light transmission rate of the electrochromic module 330 placed on the temperature controlling plate 310 based on the temperature data. For example, the controller 400 collects real-time temperature data of the supporting plate 210, and based on the temperature data, increases the light transmission rate of the electrochromic module 330 facing a locally high-temperature part of the supporting plate 210, thereby reducing the temperature of the relevant part. Accordingly, the overall temperature uniformity rate of the supporting plate 210 may be increased or improved upon. Alternatively or additionally, the controller 400 may store temperature data of the supporting plate 210 generated from the temperature sensor 240, and after the process for the substrate SB is completed, the controller 400 may provide the temperature information of the supporting plate 210 to the user.

With respect to the substrate processing apparatus 10 according to some example embodiments described through FIG. 11, other technical features other than the features described above may refer to the features of the substrate processing apparatus 10 described above through FIG. 1 to FIG. 10.

Hereinafter, with reference to FIG. 12 to FIG. 15, the substrate processing apparatus 10 including the temperature controlling member 300 according to various example embodiments is described. Regarding the substrate processing apparatus 10 according to various example embodiments below, mainly the parts that have differences from FIG. 1 to FIG. 11 are explained. Technical features other than those described may refer to the technical features of the temperature controlling member 300 and the substrate processing apparatus 10 including the same described in FIG. 1 to FIG. 11.

FIG. 12 is a cross-sectional view schematically illustrating the configuration of the substrate processing apparatus 10 according to some example embodiments.

In some example embodiments, a part of the temperature controlling plate 310 of the substrate processing apparatus 10 may be placed facing the side of the supporting plate 210. For example, referring to FIG. 12, the temperature controlling plate 310 of the substrate processing apparatus 10 may include a first temperature control part 312 arranged to face the side of the supporting plate 210, and a connecting part 311 connecting the first temperature control part 312 and the temperature control shaft 320.

In some example embodiments, at least one electrochromic module 330 may be arranged on the first temperature control part 312 of the temperature controlling plate 310. Referring to FIG. 12, the electrochromic module 330 may include the plurality of electrodes 332 and 333 arranged facing each other, and the electrochromic element 331 arranged between the plurality of electrodes 332 and 333, wherein the light transmission rate changes as the electrical energy is applied to the plurality of electrodes 332 and 333. Here, for specific details regarding the plurality of electrodes 332 and 333 and the electrochromic element 331, reference may be made to the description of the plurality of electrodes 332 and 333 and the electrochromic element 331 described above with reference to FIG. 4 and FIG. 5.

In some example embodiments, at least one electrochromic module 330 may be placed facing the side of the supporting plate 210. For example, according to the layout structure, the electrochromic module 330 may partially control the transmittance of the radiant heat emitted from the edge of the supporting plate 210 to increase the temperature uniformity of the supporting plate 210.

Meanwhile, even though not illustrated in the drawing, the electrochromic module 330 may also be placed in the connecting part 311 of the temperature controlling plate 310. For example, one or more electrochromic modules 330, whose light transmission rate changes according to the application of the electrical energy, may be arranged in the connecting part 311 of the temperature controlling plate 310. For example, the electrochromic module 330 arranged in the connecting part 311 may include the plurality of electrodes 332 and 333 facing each other in a direction perpendicular to the lower surface of the supporting plate 210 (for example, the direction D2), and the electrochromic element 331 positioned between the plurality of electrodes 332 and 333.

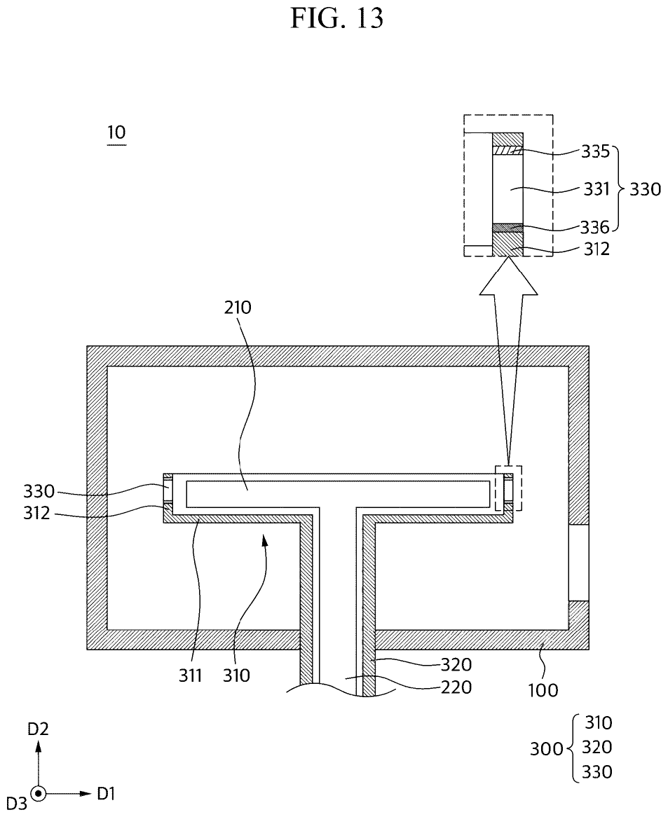

FIG. 13 is a cross-sectional diagram schematically illustrating the configuration of the substrate processing apparatus 10 according to some example embodiments.

In some example embodiments, a part of the temperature controlling plate 310 of the substrate processing apparatus 10 may be placed facing the side of the supporting plate 210. For example, referring to FIG. 13, the temperature controlling plate 310 of the substrate processing apparatus 10 may include the first temperature control part 312 arranged to face the side of the supporting plate 210, and the connecting part 311 for connecting the first temperature control part 312 and the temperature control shaft 320.

In some example embodiments, at least one electrochromic module 330 may be arranged on the first temperature control part 312 of the temperature controlling plate 310. The electrochromic module 330 may partially control the transmittance of the radiant heat emitted from the edge of the supporting plate 210 to increase the temperature uniformity of the supporting plate 210.

In some example embodiments, the electrochromic module 330 may be placed facing the side of the supporting plate 210, and the electrochromic module 330 may include the plurality of electrodes 335 and 336 spaced apart along the height direction of the chamber (for example, the direction D2), and the electrochromic element 331, which is arranged between the plurality of electrodes 335 and 336 and of which the light transmission rate changes as the electrical energy is applied to the plurality of electrodes 335 and 336. When the plurality of electrodes 335 and 336 are arranged vertically so as not to obstruct the light transmission path, the electrochromic module 330 may be implemented by utilizing various electrodes. Thus, the range of materials for the electrodes 335 and 336 may be increased, and the cost of manufacturing electrochromic modules 330 may be reduced.

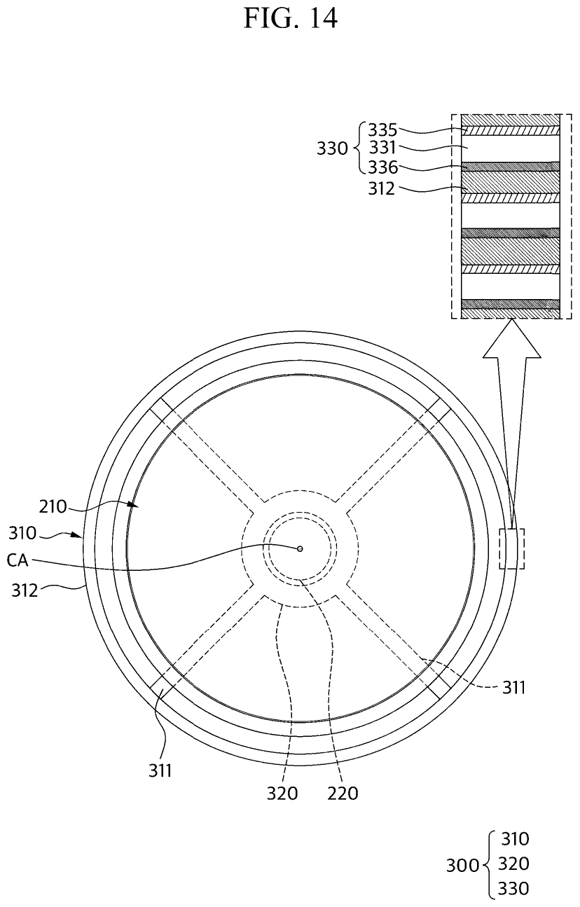

FIG. 14 is an exemplary plan view of a substrate supporting member and the temperature controlling member 300 according to some example embodiments.

In some example embodiments, a part of the temperature controlling plate 310 of the substrate processing apparatus 10 may be placed facing the side of the supporting plate 210. For example, referring to FIG. 14, the temperature controlling plate 310 of the substrate processing apparatus 10 may include the first temperature control part 312 arranged to face the side of the supporting plate 210 and the connecting part 311 connecting the first temperature control part 312 and the temperature control shaft 320.

In some example embodiments, the plurality of electrochromic modules 330 may be arranged in the first temperature control part 312 of the temperature controlling plate 310. The plurality of electrochromic modules 330 may be spaced apart along the circumferential direction with respect to the central axis CA of the supporting plate 210. The electrochromic module 330 may partially control the transmittance of the radiant heat emitted from the edge of the supporting plate 210 to increase the temperature uniformity of the supporting plate 210.

In some example embodiments, the electrochromic module 330 may be placed facing the side of the supporting plate 210, and the electrochromic module 330 may include the plurality of electrodes 335 and 336 spaced apart along the circumferential direction with respect to the central axis CA of the supporting plate 210, and the electrochromic element 331 which is arranged between the electrodes 335 and 336 and in which the light transmission rate changes as the electrical energy is applied to the plurality of electrodes 335 and 336. When the multiple electrodes 335 and 336 are arranged in this way so as not to obstruct the light transmission path, the electrochromic module 330 may be implemented by utilizing various electrodes. Thus, the range of materials for the electrodes 335 and 336 may be increased, and the cost of manufacturing the electrochromic modules 330 may be reduced.

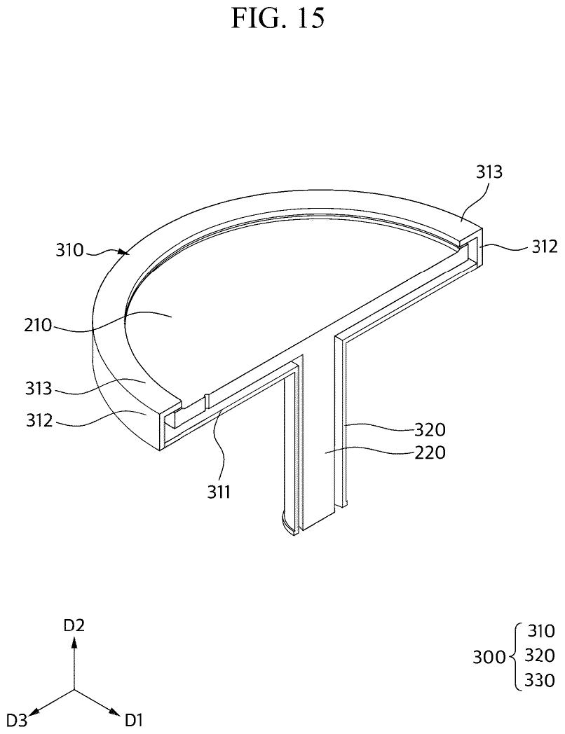

FIG. 15 is a reference diagram for explaining the structure of the temperature controlling member 300 according to some example embodiments.

In some example embodiments, a portion of the temperature controlling plate 310 included in the substrate processing apparatus 10 may be positioned to face the side and the upper surface of the supporting plate 210. For example, referring to FIG. 15, the temperature controlling plate 310 may include the first temperature control part 312 arranged to face the side of the supporting plate 210, and a second temperature control part 313 extending from the first temperature control part 312 and positioned facing a portion of the upper surface of the supporting plate 210, and the connecting part 311 connecting the first temperature control part 312 and the temperature control shaft 320.

In some example embodiments, one or more electrochromic modules may be placed in the first temperature control part 312, the second temperature control part 313 and the connecting part 311. As with the electrochromic module 330 described above with reference to FIG. 1 to FIG. 14, the electrochromic module may be configured to change appropriately increase or decrease the transmittance of the radiation heat emitted from the supporting plate 210 with the change of the light transmission rate as the electrical energy is applied. For specific technical features of the electrochromic module, reference may be made to the description of the electrochromic module 330 with reference to FIG. 1 to FIG. 14.

As illustrated in FIG. 15, the temperature controlling plate 310 may be placed facing not only the lower surface and side of the supporting plate 210, but also a portion of the upper surface, and the electrochromic module may be placed in each part of the temperature controlling plate 310, for the more effective temperature control of the supporting plate 210.

As such, according to some example embodiments, the substrate processing apparatus 10 may change the light transmission rate and the radiation heat transmittance of the temperature controlling member 300 by including the electrochromic module 330 whose light transmission rate changes according to the application of the electrical energy. Accordingly, the substrate processing apparatus 10 may increase or improve the temperature uniformity of the supporting plate 210 that supports the substrate SB.

Specifically, the temperature controlling member 300 of the substrate processing apparatus 10 according to the example embodiments may adjust the light transmission rate and the radiation heat transmittance of the electrochromic module 330 in various ways by controlling the magnitude of the electrical energy applied to the electrochromic module 330. Further, the light transmission rate and the radiation heat transmittance of the temperature controlling member 300 may be locally changed by applying the electrical energy to only some of the plurality of electrochromic modules 330 or by applying the electrical energy only to a part of the electrochromic module 330, and thus the temperature of the supporting plate 210 and further the temperature of the substrate SB may be controlled more precisely. Accordingly, according to example embodiments, the substrate processing apparatus 10 may improve the temperature uniformity of the substrate SB.

Alternatively or additionally, according to some example embodiments, the substrate processing apparatus 10 may electronically control the radiation heat transmittance of the temperature controlling member 300 through the controller 400. Accordingly, the temperature uniformity rate of the substrate supporting member 200 and the substrate may be adjusted while maintaining the process environment without having to open the chamber 100 to adjust the temperature uniformity rate of the substrate. For example, in-situ temperature control of the substrate SB may be possible by the temperature controlling member 300 of the substrate processing apparatus 10 according to example embodiments, and thus the efficiency and precision of the semiconductor manufacturing process may be greatly increased.

Alternatively or additionally, the structure of the chamber 100 or the internal environment of the chamber 100 may be different for each semiconductor manufacturing facility: however, since the temperature controlling member 300 according to the embodiments may change the light transmission rate of the electrochromic module 330 in various ways in response to these various environments of the chamber 100, the temperature controlling member 300 may be universally applied to semiconductor manufacturing facilities. Further, since the same temperature controlling member 300 may be applied without having to manufacture the separate temperature controlling member 300 for each facility, the manufacturing efficiency of semiconductor manufacturing facilities may be improved and manufacturing costs may be reduced.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

In the above, various example embodiments are described in detail. However, it will be apparent to those with average knowledge in the technical field that scope of rights of this disclosure is not limited thereto, and various modifications and variations are possible without departing from the technical spirit of the present disclosure as set forth in the claims. Further, the above-described example embodiments may be implemented with some elements deleted, and each example embodiment may be implemented in combination with each other. Additionally, example embodiments are not necessarily mutually exclusive with one another. For example, some example embodiments may include one or more features described with reference to one or more figures, and may also include one or more other features described with reference to one or more other figures.

What is claimed is:

1. A substrate processing apparatus comprising:
a chamber defining a substrate processing space;
a supporting plate inside the chamber and comprising an upper surface configured to seat a substrate;
a temperature controlling plate facing at least a portion of the supporting plate; and
at least one electrochromic module at the temperature controlling plate, and configured to change light transmittance depending on an applied electrical energy.

2. The substrate processing apparatus of claim 1, wherein the at least one electrochromic module comprises:
a pair of electrodes facing each other; and
an electrochromic element between the pair of electrodes, and the electrochromic element configured to operate such that light transmittance changes depending on magnitude of a voltage applied to the pair of electrodes.

3. The substrate processing apparatus of claim 2, wherein the electrochromic element comprises at least one of polymer dispersed liquid crystal (PDLC), suspended particle display (SPD) or guest-host liquid crystal (G-H LC).

4. The substrate processing apparatus of claim 2, further comprising:
a support shaft supporting a lower surface of the supporting plate; and
a temperature control shaft surrounding the support shaft and supporting the temperature controlling plate.

5. The substrate processing apparatus of claim 4, further comprising:
a conductive connecting line electrically connected to the pair of electrodes and configured to transmit power to the pair of electrodes,
wherein at least a portion of the conductive connecting line is inside the temperature control shaft.

6. The substrate processing apparatus of claim 2, further comprising:
a controller configured to control a magnitude of the voltage applied to the pair of electrodes.

7. The substrate processing apparatus of claim 6, further comprising:
a power supply part configured to supply power to the at least one electrochromic module,
wherein the power supply part is inside the chamber.

8. The substrate processing apparatus of claim 6, further comprising:
a temperature sensor configured to measure temperature of the supporting plate.

9. The substrate processing apparatus of claim 8, wherein the controller is configured to control the magnitude of the voltage applied to the at least one electrochromic module based on temperature information of the supporting plate, the temperature information measured by the temperature sensor.

10. The substrate processing apparatus of claim 2, wherein the pair of electrodes are spaced in a direction perpendicular to the lower surface of the supporting plate.

11. The substrate processing apparatus of claim 10, wherein each of the pair of electrodes is a transparent electrode.

12. The substrate processing apparatus of claim 10, wherein at least one of the pair of electrodes is a lattice type electrode on one side of the electrochromic element.

13. The substrate processing apparatus of claim 2, wherein the pair of electrodes are spaced in a radial direction with respect to a central axis of the temperature controlling plate.

14. The substrate processing apparatus of claim 1, wherein
the at least one electrochromic module comprises a first electrochromic module and a second electrochromic module spaced apart from each other in a radial direction with respect to a central axis of the temperature controlling plate, and
the first electrochromic module and the second electrochromic module are configured to change light transmittance independently.

15. The substrate processing apparatus of claim 1, wherein
the at least one electrochromic module comprises a plurality of electrochromic modules, and
the plurality of electrochromic modules are spaced apart from each other in a circumferential direction based on a central axis of the temperature controlling plate.

16. The substrate processing apparatus of claim 1, wherein the temperature controlling plate is movable with respect to the supporting plate.

17. A substrate processing apparatus comprising:
a chamber defining a substrate processing space;
a supporting plate inside the chamber, and configured to heat a substrate seated on an upper surface of the supporting plate;
a temperature controlling plate facing at least a portion of the supporting plate;
a penetration part penetrating the temperature controlling plate; and
an electrochromic module at the penetration part, and configured to change light transmittance as electrical energy is applied.

18. The substrate processing apparatus of claim 17, wherein the electrochromic module further comprises:
an electrochromic element configured to change transmittance as a voltage is applied; and
a plurality of electrodes on one side and another side of the electrochromic element,
wherein at least one of the plurality of electrodes includes at least one of a transparent electrode or a lattice type electrode.

19. A substrate processing apparatus comprising:
a chamber defining a substrate processing space;
a supporting plate inside the chamber, and configured to heat a substrate seated on an upper surface of the supporting plate;
a temperature controlling plate facing at least a portion of the supporting plate;
a first electrochromic module and a second electrochromic module at different positions on the temperature controlling plate, and the first electrochromic module and the second electrochromic module respectively configured to change light transmittance as respective electrical energy is applied; and
a controller configured to independently control a magnitude of the electrical energy applied to the first electrochromic module and a magnitude of the electrical energy applied to the second electrochromic module.

20. The substrate processing apparatus of claim 19, wherein the controller is configured to wirelessly control light transmittance of the first electrochromic module and light transmittance of the second electrochromic module.
